(19) United States
(12) Patent Application Publication
(10) Pub. No.: US 2016/0247917 A1
(43) Pub. Date: Aug. 25, 2016

(54) SEMICONDUCTOR DEVICE

(71) Applicant: KABUSHIKI KAISHA TOSHIBA, Tokyo (JP)

(72) Inventors: Yoshiyuki KONDO, Yokohama Kanagawa (JP); Akira HOKAZONO, Kawasaki Kanagawa (JP)

(73) Assignee: KABUSHIKI KAISHA TOSHIBA, Tokyo (JP)

(21) Appl. No.: 14/735,945

(22) Filed: Jun. 10, 2015

(30) Foreign Application Priority Data
Feb. 24, 2015 (JP) 2015-034189

(51) Int. Cl. H01L 29/78; H01L 29/417; H01L 29/423

(52) U.S. Cl. CPC H01L 29/7835; H01L 29/42368; H01L 29/41758

(57) ABSTRACT

A semiconductor device according to an embodiment includes a semiconductor layer. A gate dielectric film is provided on a surface of the semiconductor layer. A gate electrode includes a first gate part and a second gate part. The first gate part and the second gate part are provided on the semiconductor layer via the gate dielectric film. The first gate part and the second gate part have work functions respectively different from each other, and are electrically connected to each other. A drain layer of a first conductivity type is provided in the semiconductor layer on a side of one end of the gate electrode. A source layer of a second conductivity type is provided in the semiconductor layer on a side of the other end of the gate electrode and below the gate electrode. The source layer below the gate electrode has a substantially uniform impurity concentration.

### CROSS REFERENCE TO RELATED APPLICATIONS

This application is based upon and claims the benefit of priority from the prior Japanese Patent Application No. 2015-034189, filed on Feb. 24, 2015, the entire contents of which are incorporated herein by reference.

### FIELD

The embodiments of the present invention relate to a semiconductor device.

### BACKGROUND

In recent years, a TFET (Tunnel Field-Effect Transistor) using a quantum-mechanical effect of electrons has been developed. In the TFET, BTBT (Band To Band Tunneling) is generated between a source layer and a channel part by applying a voltage to a gate electrode. This brings the TFET to an on-state. In order to lower a power supply voltage to suppress power consumption in the TFET, variation in electrical characteristics (a threshold voltage, for example) of the TFET needs to be reduced. For example, in order to reduce variation in the threshold voltage, a suppression of parasitic BTBT to improve sub-threshold swing characteristics (hereinafter, also “SS characteristics”) of the TFET is demanded.

### BRIEF DESCRIPTION OF THE DRAWINGS

FIG. 1 is a schematic cross-sectional view showing an example of a configuration of an N-TFET 100 according to a first embodiment;

FIGS. 2 to 4 are energy band diagrams showing an example of an operation of the TFET 100 according to the first embodiment;

FIG. 5 is a graph showing the SS characteristics of the TFET 100 according to the first embodiment;

FIGS. 6A to 12B are cross-sectional views showing an example of the manufacturing method of the TFET 100 according to the first embodiment;

FIG. 13 is a schematic cross-sectional view showing an example of a configuration of an N-TFET 200 according to a second embodiment;

FIG. 14 illustrates energy band diagrams showing an example of an operation of the TFET 200 according to the second embodiment;

FIG. 15 illustrates energy band diagrams of a TFET in which the first and second gate parts 41 and 42 have the same work function; and

FIGS. 16A to 21 are cross-sectional views showing an example of the manufacturing method of the TFET 200 according to the second embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor layer on which semiconductor elements are provided is assumed as “an upper direction”. Therefore, the term “upper direction” or “lower direction” occasionally differs from an upper direction or a lower direction based on a gravitational acceleration direction.

A semiconductor device according to an embodiment includes a semiconductor layer. A gate dielectric film is provided on a surface of the semiconductor layer. A gate electrode includes a first gate part and a second gate part. The first gate part and the second gate part are provided on the semiconductor layer via the gate dielectric film. The first gate part and the second gate part have work functions respectively different from each other, and are electrically connected to each other. A drain layer of a first conductivity type is provided in the semiconductor layer on a side of one end of the gate electrode. A source layer of a second conductivity type is provided in the semiconductor layer on a side of the other end of the gate electrode and below the gate electrode. The source layer below the gate electrode has a substantially uniform impurity concentration.

### First Embodiment

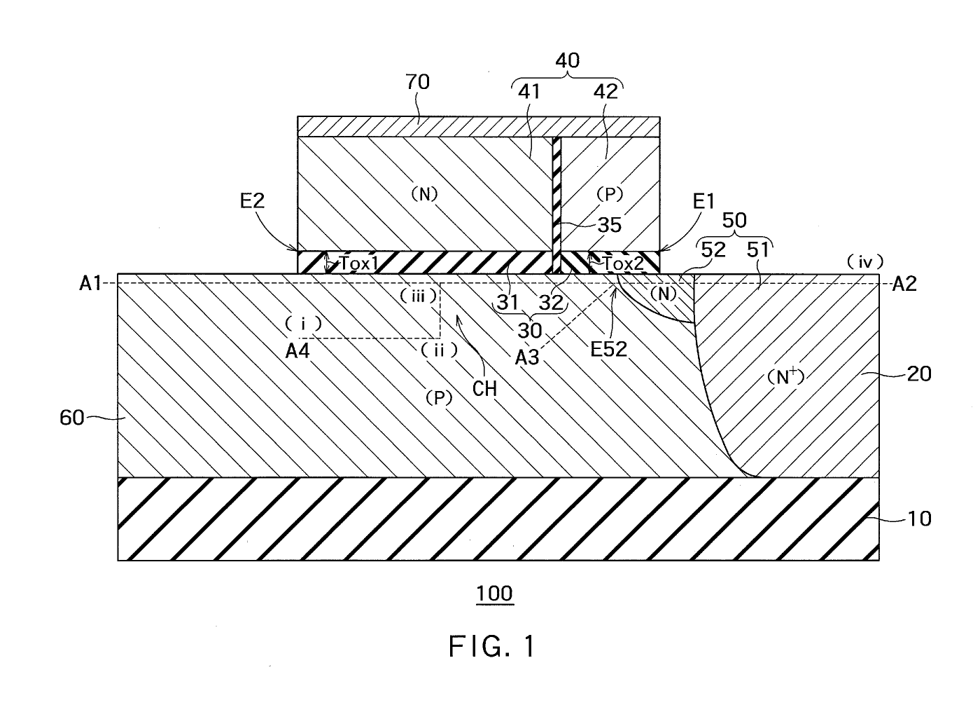

FIG. 1 is a schematic cross-sectional view showing an example of a configuration of an N-TFET 100 according to a first embodiment. The TFET 100 can be used for a logic semiconductor integrated circuit such as a microprocessor or an ASIC (Application Specific Integrated Circuit). In FIG. 1, an interlayer dielectric film and a wiring structure on a gate electrode 40, a drain layer 50, and a source layer 60 are not shown.

The TFET 100 includes a BOX (Buried Oxide) layer 10, a semiconductor layer 20, a gate dielectric film 30, the gate electrode 40, the drain layer 50, the source layer 60, and a silicide layer 70.

The semiconductor layer 20 is a SOI (Silicon On Insulator) layer provided on the BOX layer 10. The semiconductor layer 20 can be a SOI layer of a SOI substrate or can be a SiGe layer of a SiGe—OI substrate, a Ge layer of a Ge—OI substrate, a silicon layer formed of a silicon substrate, or a semiconductor layer using a III-V compound semiconductor substrate. Alternatively, the semiconductor layer 20 can be a semiconductor layer epitaxially grown on an arbitrary substrate.

The gate dielectric film 30 is an insulating film provided on a surface of the semiconductor layer 20 and is formed of, for example, a silicon dioxide film or a dielectric material having a higher dielectric constant than that of the silicon dioxide film. The gate dielectric film 30 includes a first gate dielectric film 31 and a second gate dielectric film 32. The first gate dielectric film 31 and the second gate dielectric film 32 can be formed of the same material. While a film thickness Tox1 of the first gate dielectric film 31 is substantially equal to a film thickness Tox2 of the second gate dielectric film 32, the film thicknesses Tox1 and Tox2 can be slightly different from each other, as described later.

The gate electrode 40 includes a first gate part 41 and a second gate part 42. The first gate part 41 and the second gate part 42 are provided on the semiconductor layer 20 via the first gate dielectric film 31 and the second gate dielectric film 32, respectively (or with the first gate dielectric film 31 and the second gate dielectric film 32 interposed therebetween, respectively). The first gate part 41 and the second gate part 42 are adjacent to each other, and an insulating film 35 is provided between the first gate part 41 and the second gate part 42. The first gate part 41 and the second gate part 42 are electrically connected to each other by the silicide layer 70. While being used during formation of the first gate part 41 and the second gate part 42, the insulating film 35 is not required for characteristics of the TFET 100. The insulating film 35 is formed sufficiently thinly not to affect the characteristics (an on-resistance, for example) of the TFET 100.

The first gate part 41 is provided on the side of the source layer 60 and is formed of, for example, N-doped polysilicon. The second gate part 42 is provided on the side of the drain layer 50 and is formed of, for example, P-doped polysilicon. Therefore, the first gate part 41 and the second gate part 42 have different work functions. In the first embodiment, the second gate part 42 is larger in the work function than the first gate part 41. Accordingly, the TFET 100 according to the first embodiment is brought to a conduction state by BTBT occurring in a channel part CH below the first gate part 41 while suppressing BTBT parasitically occurring at an end E52 of the drain layer 50 below the second gate part 42. A gate length of the first gate part 41 is larger than that of the second gate part 42. This enables an enlargement of a facing area between a bottom surface of the first gate part 41 and a surface of the source layer 60. When the facing area between the bottom surface of the first gate part 41 and the surface of the source layer 60 is large, a current flowing in the channel part CH due to BTBT is increased, which leads to an improvement in the SS characteristics. A more detailed operation of the TFET 100 is explained later.

The N-type drain layer 50 includes an N⁺-type deep layer 51 and an N-type extension layer 52. The N-type drain layer 50 is provided in the semiconductor layer 20 on the side of one end E1 of the gate electrode 40. The extension layer 52 is shallower (thinner) than the deep layer 51 and is lower in the impurity concentration than the deep layer 51. The extension layer 52 is provided in a surface region of the semiconductor layer 20 in such a manner as to extend from the deep layer 51 to the gate electrode 40. Therefore, the end E52 of the extension layer 52 is located below the second gate part 42 and at least a part of a surface of the extension layer 52 faces a bottom surface of the second gate part 42. That is, when viewed from above the surface of the semiconductor layer 20, at least a part of the surface of the extension layer 52 overlaps with the bottom surface of the second gate part 42.

If the deep layer 51 extends to the end E1 of the gate electrode 40 without the extension layer 52 provided, a GIDL (Gate Induced Drain Leakage) current may occur during a standby (off) time and the SS characteristics may be degraded. In order to suppress such degradation in the SS characteristics, it is preferable to form the shallow (or thin) and low-concentration extension layer 52.

The P-type source layer 60 is provided in the semiconductor layer 20 on the side of the other end E2 of the gate electrode 40 and below the gate electrode 40. In the first embodiment, almost the whole of the bottom surface of the gate electrode 40 faces the source layer 60. That is, the source layer 60 is provided in the semiconductor layer 20 to extend from the other end E2 of the gate electrode 40 to a vicinity of the end E1 of the gate electrode 40 across a portion below the bottom surface of the gate electrode 40. Therefore, the channel part CH below the gate electrode 40 has the same conductivity type as that of the source layer 60 and an impurity concentration of the channel part CH is substantially equal to that of the source layer 60. That is, there is no junction part between the source layer 60 and the channel part CH and the concentration gradient is gentle. The source layer 60 and the channel part CH extend at substantially uniform impurity concentrations. Accordingly, the channel part CH is defined as a facing region between the bottom surface of the gate electrode 40 and the source layer 60. As described above, the TFET 100 is a so-called source junctionless TFET (hereinafter, also “SJL-TFET”) having no junction part on the source side.

The silicide layer 70 is provided on the gate electrode 40. The silicide layer 70 is, for example, a metal silicide obtained by a reaction between a metal such as Ni, Co, or Ti and silicon. The silicide layer (not shown in FIG. 1) is also provided on the drain layer 50 and the source layer 60.

Although not shown in FIG. 1, a sidewall film is provided on side surfaces of the gate electrode 40. Furthermore, a wiring structure including contacts, metal wires, an interlayer dielectric film, and the like is provided on the gate electrode 40, the drain layer 50, and the source layer 60.

In the SJL-TFET, if an end of the drain layer is located below the gate electrode, BTBT is more likely to occur in a junction part between the end of the drain layer and a channel part (an inverted region) below the gate electrode than in the channel part. In this case, the SS characteristics are degraded.

On the other hand, if the end of the drain layer is offset from the gate electrode toward the drain layer to prevent the drain layer from facing the bottom surface of the gate electrode, BTBT occurs in the channel part below the gate electrode. However, if the end of the drain layer is separated too much from the gate electrode, an on-current flowing between the source and the drain becomes small or the on-current does not flow.

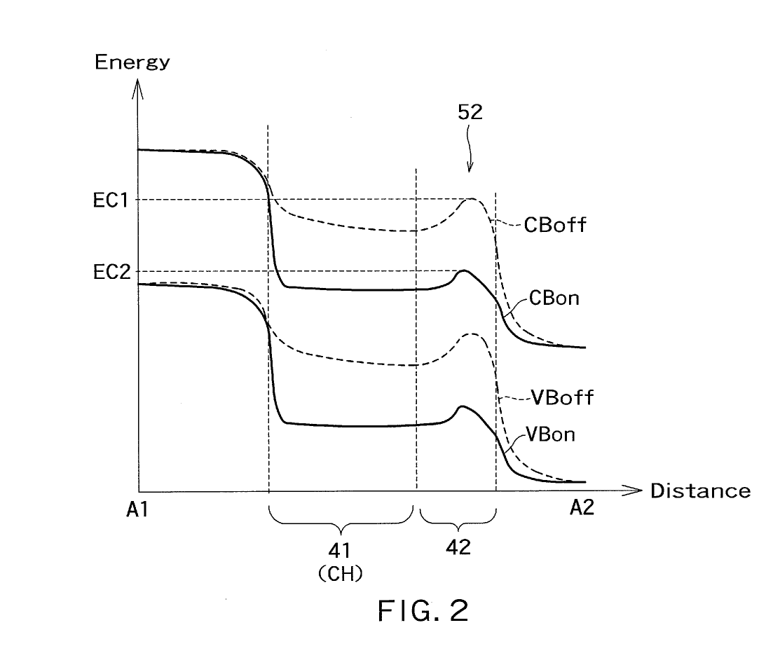

In the TFET 100 according to the first embodiment, the gate electrode 40 is thus divided into a plurality of parts and includes the first gate part 41 and the second gate part 42. The second gate part 42 is electrically shortcircuited with the first gate part 41 by the silicide layer 70. Therefore, the same gate voltage is applied to the first gate part 41 and the second gate part 42. However, in the first embodiment, the second gate part 42 is larger in the work function than the first gate part 41. Accordingly, an energy level in the semiconductor layer 20 below the second gate part 42 is shifted toward a vacuum level. Energy bands in the semiconductor layer 20 are explained with reference to energy band diagrams shown in FIGS. 2 to 4.

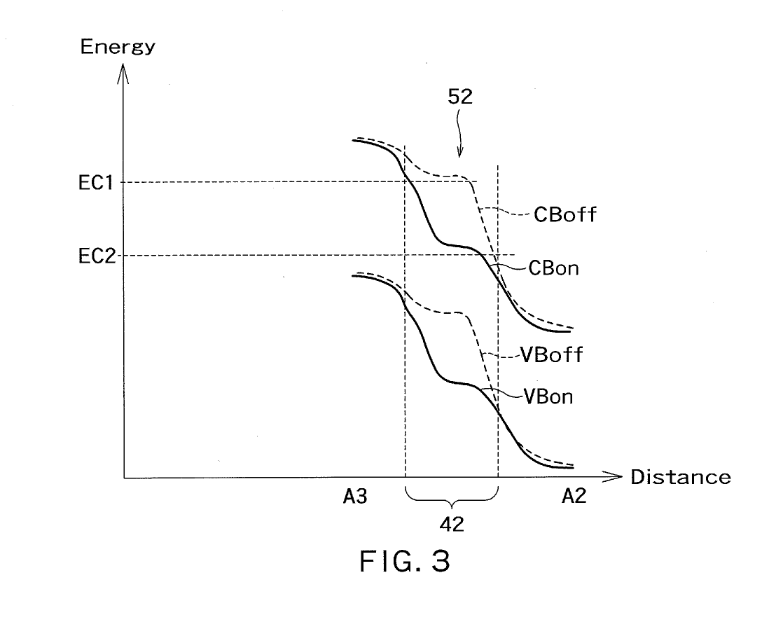

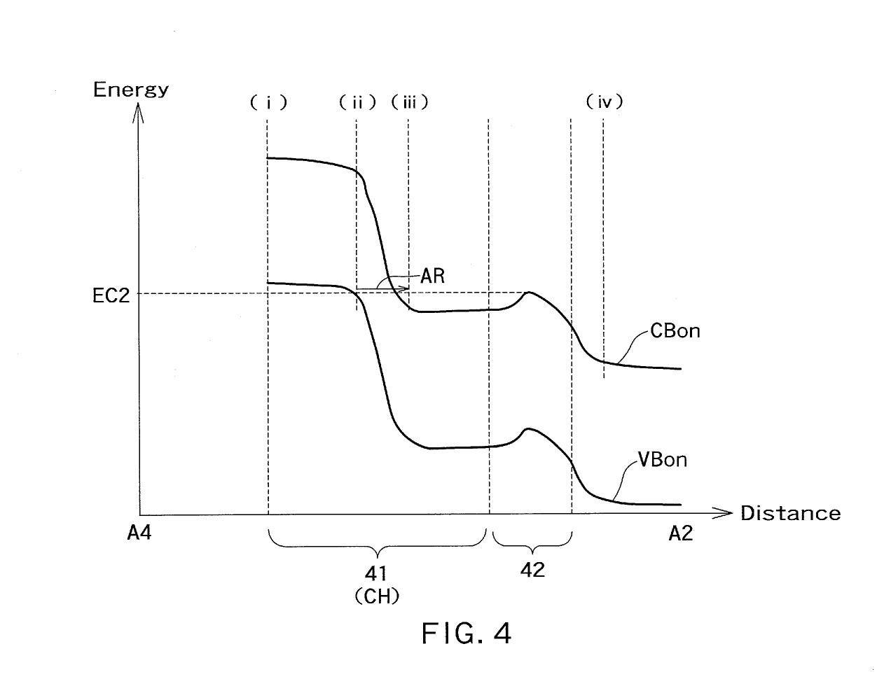

FIGS. 2 to 4 are energy band diagrams showing an example of an operation of the TFET 100 according to the first embodiment. FIG. 2 illustrates energy band diagrams at a position along a line A1-A2 in FIG. 1. FIG. 3 illustrates energy band diagrams at a position along a line A3-A2 in FIG. 1. FIG. 4 illustrates energy band diagrams at a position along a line A4-A2 in FIG. 1. The line A4-A2 is a line from a point (i) to a point (iv) through points (ii) and (iii) in FIG. 1.

CBoff and VBoff shown by dashed lines in FIGS. 2 and 3 are energy band diagrams in a case where the TFET 100 is in an off-state. CBon and VBon shown by solid lines in FIGS. 2 to 4 are energy band diagrams in a case where the TFET 100 is in an on-state. CBoff and CBon indicate energy levels of a conduction band and VBoff and VBon indicate energy levels of a valence band, respectively. EC1 and EC2 indicate maximum values of the energy levels of the conduction band in the extension layer 52, respectively. EC1 is a maximum value in a case where the TFET 100 is in an off-state and EC2 is a maximum value in a case where the TFET 100 is in an on-state. Hereinafter, EC1 is referred to as “off maximum value” and EC2 is referred to as “on maximum value”.

It is assumed, for example, that 0 volt is applied to the source layer 60 and that a positive voltage (1 volt, for example) is applied to the drain layer 50. That is, when the TFET 100 is in an off-state, a reverse bias is applied to a PN junction part between the source layer 60 and the drain layer 50. When the TFET 100 is to be brought to an on-state, voltages of the same polarity are applied to the gate electrode 40 and the drain layer 50, respectively. That is, when the TFET 100 is to be brought to an on-state, a positive voltage is applied to the gate electrode 40 as mentioned below.

When an application voltage to the gate electrode 40 is lower than a threshold voltage, the TFET 100 is in an off-state. At that time, because the off maximum value EC1 of the extension layer 52 is sufficiently higher than the energy level VBoff of the valence band as shown in FIG. 2, BTBT in the channel part CH and BTBT in the PN junction part between the channel part CH and the extension layer 52 are both prohibited. That is, although quite a small current (an off-leakage current) due to the reverse bias flows in the PN junction part between the source layer 60 and the drain layer 50, the TFET 100 is substantially in an off-state.

When a positive voltage is applied to the gate electrode 40 with respect to a source voltage, the channel part CH starts depleting. Accordingly, the energy bands in the channel part CH below the gate electrode 40 are bent toward the valence band. When the energy bands become a state shown by CBon and VBon in FIG. 2, the on maximum value EC2 of the extension layer 52 is still higher than the energy level VBoff of the valence band on the side of A1 (the side of the source layer 60) and thus the BTBT in the PN junction part between the channel part CH and the extension layer 52 is kept prohibited.

Energy bands near the end E52 of the extension layer 52 along the line A3-A2 in FIG. 1 at that time are illustrated in FIG. 3. With reference to FIG. 3, it can be seen that the on maximum value EC2 of the extension layer 52 is higher at the end E52 of the extension layer 52 (the PN junction part between the source layer 60 and the drain layer 50) than the energy level VBon of the valence band on the side of A3 (the side of the source layer 60). Therefore, as mentioned above, no BTBT occurs in the PN junction part between the source layer 60 and the drain layer 50.

In contrast thereto, as shown in FIG. 4, it can be seen that the on maximum value EC2 of the extension layer 52 is equal to or lower than the energy level VBon of the valence band between the points (ii) and (iii) in the channel part CH below the first gate part 41. Therefore, BTBT occurs in a vertical direction (a direction substantially orthogonal to the surface of the semiconductor layer 20) between the points (ii) and (iii). That is, while not occurring in the PN junction part between the source layer 60 and the drain layer 50, BTBT occurs in the channel part CH below the first gate part 41. In the energy band diagrams illustrated in FIG. 4, only BTBT between the points (ii) and (iii) is shown. However, the vertical BTBT occurs in the whole channel part CH (the whole surface region of the source layer 60 facing the first gate part 41).

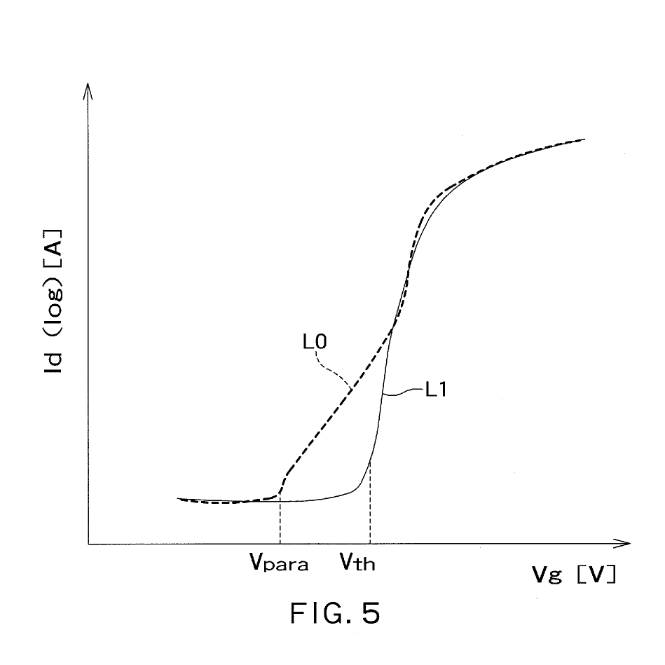

As described above, the TFET 100 according to the first embodiment can generate vertical BTBT in the channel part CH (hereinafter, also “BTBT in the channel part CH”) below the first gate part 41 while suppressing parasitic BTBT in the PN junction part (hereinafter, also “BTBT in the PN junction part”) between the source layer 60 (the channel part CH) and the drain layer 50 by setting the work function of the second gate part 42 to be larger than that of the first gate part 41. Accordingly, the SS characteristics of the TFET 100 are improved, as explained with reference to FIG. 5.

FIG. 5 is a graph showing the SS characteristics of the TFET 100 according to the first embodiment. The horizontal axis represents the gate voltage Vg. The vertical axis represents the drain current Id (in logarithmic expression). A line L0 indicates SS characteristics of a TFET having an undivided single gate electrode. A line L1 indicates the SS characteristics of the TFET 100 according to the first embodiment.

As indicated by the line L0, in the TFET having a single gate electrode, BTBT in the PN junction part occurs when the gate voltage Vg is Vpara and then BTBT in the channel part CH occurs when the gate voltage Vg is Vth. Vpara is a threshold voltage of the BTBT in the PN junction part. Vth is a threshold voltage of the BTBT in the channel part CH. If the threshold voltage Vpara is lower than the threshold voltage Vth and the parasitic BTBT in the PN junction part occurs earlier than the BTBT in the channel part CH, the SS characteristics are degraded.

In contrast thereto, because the work function of the second gate part 42 is larger than that of the first gate part 41 in the TFET 100 according to the first embodiment, the threshold voltage Vpara becomes higher than the threshold voltage Vth and the BTBT in the channel part CH occurs earlier than the BTBT in the PN junction part as indicated by the line L1. That is, when the gate voltage Vg is increased and the gate voltage Vg becomes the threshold voltage Vth, the BTBT in the channel part CH occurs while the BTBT in the PN junction part is suppressed. Because the BTBT in the channel part CH can occur in the whole facing surface between the bottom surface of the first gate part 41 and the surface of the source layer 60, the BTBT in the channel part CH enables a larger current to flow as compared to the BTBT in the PN junction part. Therefore, as shown in FIG. 5, the SS characteristics become quite steep.

As described above, in the first embodiment, the end E52 of the extension layer 52 is located below the second gate part 42, and the surface of the extension layer 52 faces the bottom surface of the gate electrode 40. However, by setting the work function of the second gate part 42 to be larger than that of the first gate part 41, the threshold voltage Vpara can be set to be larger than the threshold voltage Vth. Accordingly, when the gate voltage is increased, the BTBT in the channel part CH occurs earlier than the BTBT in the PN junction part. The BTBT in the channel part CH occurs in the surface area of the source layer 60 facing the bottom surface of the first gate part 41. The BTBT in the channel part CH thus can occur in a wider area than the BTBT in the PN junction part. Therefore, a large drain current Id flows at voltages near the threshold voltage Vth shown in FIG. 5 and steep SS characteristics can be obtained.

The threshold voltage of the TFET 100 is not affected so much by the BTBT in the PN junction part and is determined by the BTBT in the channel part CH. That is, the BTBT in the channel part CH becomes dominant and the threshold voltage of the TFET 100 is determined by the threshold voltage Vth rather than the threshold voltage Vpara. Accordingly, even when the position of the end E52 of the extension layer 52 (the position of the PN junction part) varies, variation in the threshold voltage of the TFET 100 is suppressed. This enables to stabilize the threshold voltage and the SS characteristics of the TFET 100 regardless of the position of the end E52 of the extension layer 52. As a result, the power supply voltage and the power consumption of the TFET 100 can be reduced.

As described above, the film thickness Tox1 of the first gate dielectric film 31 can be substantially equal to or slightly different from the film thickness Tox2 of the second gate dielectric film 32. For example, the film thickness Tox2 can be larger than the film thickness Tox1. A larger film thickness Tox2 reduces an electric field applied from the second gate part 42 to the PN junction part between the source layer 60 and the drain layer 50. This further suppresses occurrence of the BTBT in the PN junction part between the source layer 60 and the drain layer 50. A leakage current (a gate leakage current) between the gate electrode 40 and the drain layer 50 is also reduced in an off-state of the TFET 100 due to the large film thickness Tox2. On the other hand, the film thickness Tox2 can be smaller than the film thickness Tox1 as long as the BTBT in the channel part CH occurs at a lower gate voltage than that causes the BTBT in the PN junction part.

A manufacturing method of the TFET 100 according to the first embodiment is explained next.

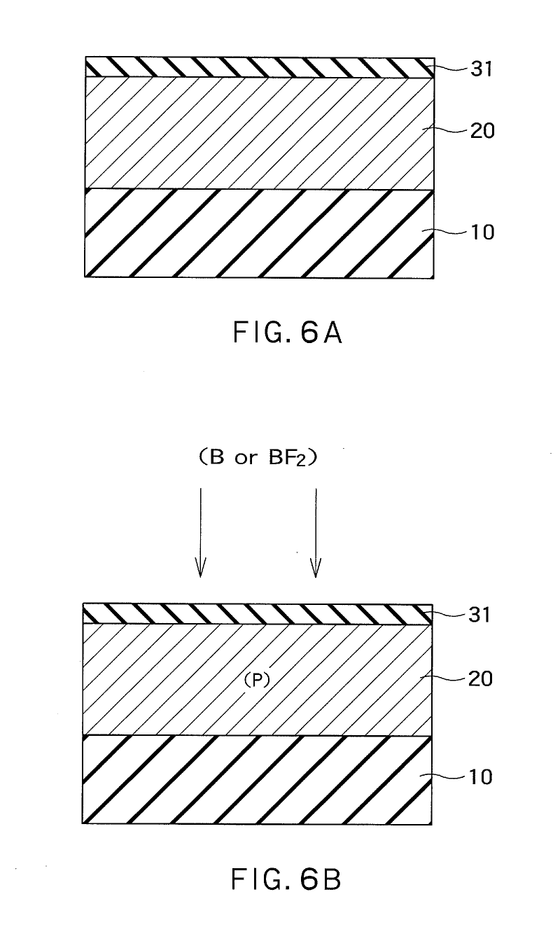

FIGS. 6A to 12B are cross-sectional views showing an example of the manufacturing method of the TFET 100 according to the first embodiment.

First, as shown in FIG. 6A, the first gate dielectric film 31 is formed on the semiconductor layer 20. The semiconductor layer 20 can be a SOI layer of a SOI substrate, a SiGe layer of a SiGe—OI substrate, a Ge layer of a Ge—OI substrate, a silicon layer formed of a silicon substrate, or a semiconductor layer using a III-V compound semiconductor substrate. Alternatively, the semiconductor layer 20 can be a semiconductor layer epitaxially grown on an arbitrary substrate.

The first gate dielectric film 31 can be a thermally-oxidized film obtained by thermally oxidizing the semiconductor layer 20 or can be a TEOS (Tetraethylorthosilicate) film, a silicon nitride film (Si₃N₄), SiON film, or a high dielectric film such as HfO₂ formed by a CVD (Chemical Vapor Deposition) method.

Next, as shown in FIG. 6B, ion implantation to the semiconductor layer 20 including a region that becomes the source layer 60 and the channel part CH is performed. Ion species to be implanted are, for example, P-type impurities such as B or BF₂. Activation annealing such as RTA (Rapid Thermal Annealing) is then performed. The source layer 60 and the channel part CH are thereby formed to have substantially uniform impurity concentrations, respectively.

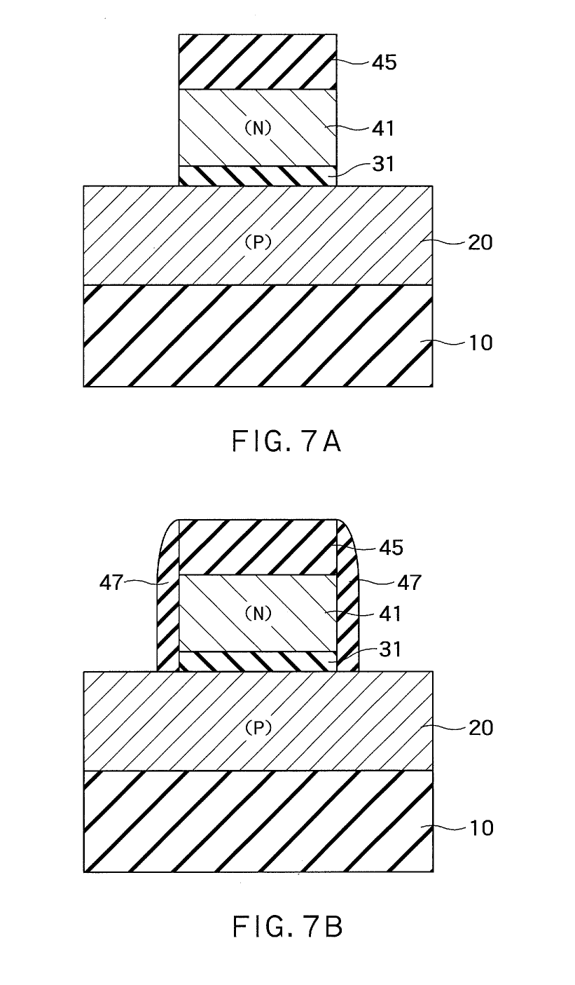

Subsequently, a material of the first gate part 41 is deposited on the first gate dielectric film 31 and a material of the hard mask 45 is deposited on the material of the first gate part 41. The material of the first gate part 41 is formed of, for example, polysilicon or polysilicon germanium doped with N-type impurities such as phosphorous or arsenic. Alternatively, the material of the first gate part 41 can be formed by implanting ions of the N-type impurities after depositing polysilicon or polysilicon germanium. The material of the hard mask 45 is formed of, for example, an insulating film such as a silicon nitride film. Next, the material of the hard mask 45 is processed into a layout pattern of the first gate part 41 using a lithography technique and a RIE (Reactive Ion Etching) method. The material of the first gate part 41 and the first gate dielectric film 31 are processed by the RIE method using the hard mask 45 as a mask. A structure shown in FIG. 7A is thereby obtained. As long as the work function of the first gate part 41 is smaller than that of the second gate part 42, any combination of the first gate part 41 and the first gate dielectric film 31 can be used. For example, a combination of the first gate part 41 and the first gate dielectric film 31 can be a combination of polysilicon and SiON or a combination of a metal gate and a high dielectric film. When the combination of the first gate part 41 and the first gate dielectric film 31 is a combination of a metal gate and a high dielectric film, a material of the metal gate can be TiN, TaOx, TaN, or the like and the high dielectric film can be HfOx, HfSiON, HfON, Al₂O₃, or the like. In this case, x is a positive number. The shape of the first gate part 41 can be a fin gate or a multilayered gate structure.

Subsequently, an insulating film such as a silicon nitride film is deposited on side surfaces of the first gate part 41 and a top surface of the hard mask 45 using the CVD method. Next, the insulating film is anisotropically etched using the RIE method, thereby leaving a spacer 47 on the side surfaces of the first gate part 41 as shown in FIG. 7B.

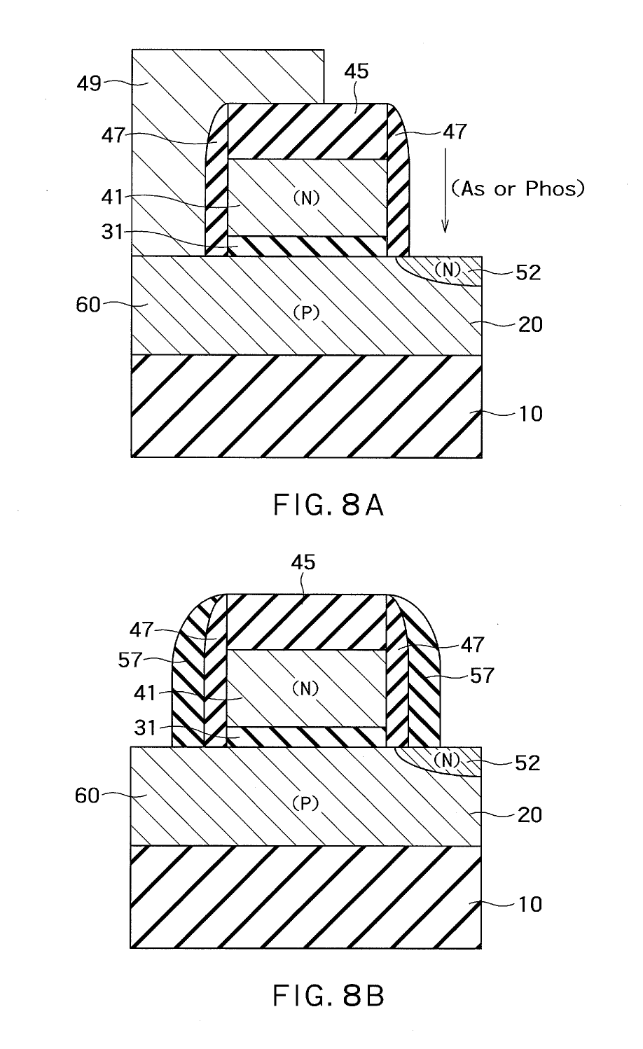

Subsequently, the source layer 60 is covered with a photoresist 49 using the lithography technique as shown in FIG. 8A. Ions of N-type impurities (phosphorous or arsenic, for example) are implanted to the semiconductor layer 20 on the drain side using the photoresist 49 as a mask. At that time, the semiconductor layer 20 on the drain side is changed from the P-type to the N-type due to implantation of the N-type impurities. The N-type impurities are locally implanted to a shallow position of the semiconductor layer 20. Activation annealing is then performed. The extension layer 52 is thereby formed.

After removal of the photoresist 49, an insulating film such as a TEOS film is further deposited on the spacer 47 and the hard mask 45 using the CVD method. Next, the insulating film is anisotropically etched using the RIE method, thereby further leaving a sidewall film 57 on side surfaces of the spacer 47 as shown in FIG. 8B. In this way, the spacer 47 and the sidewall film 57 are formed on the side surfaces of the first gate part 41.

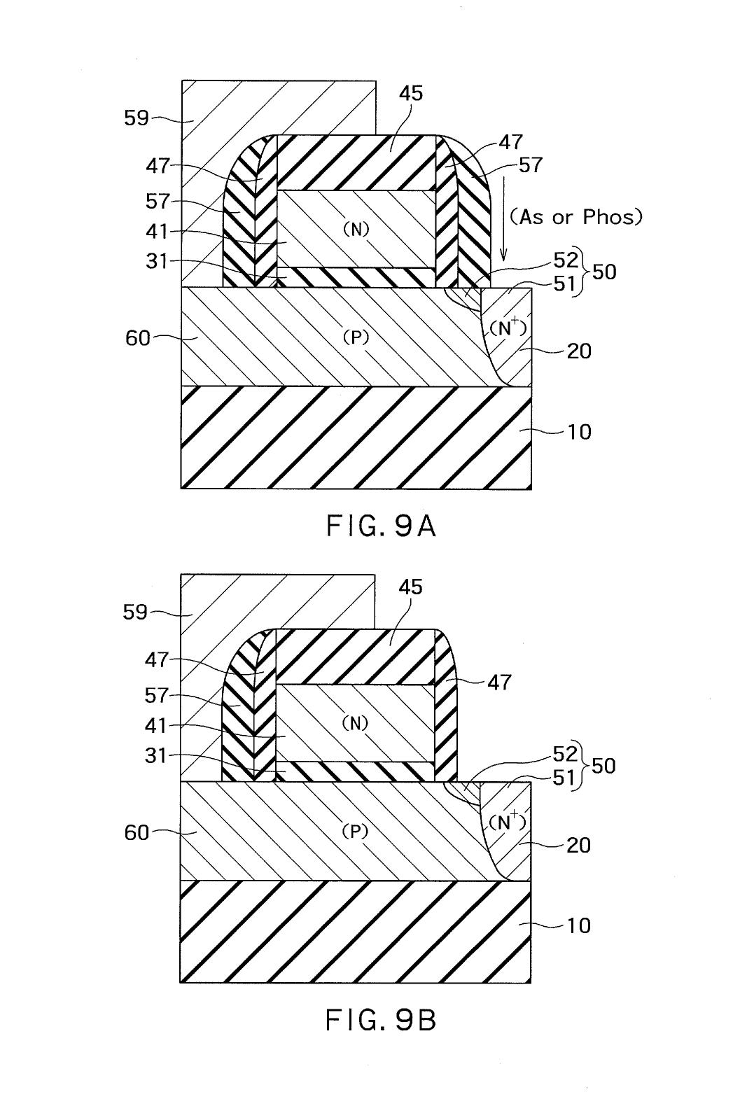

Subsequently, as shown in FIG. 9A, the source layer 60 is covered with a photoresist 59 using the lithography technique. Ions of N-type impurities (phosphorous or arsenic, for example) are implanted to the semiconductor layer 20 on the drain side using the photoresist 59 as a mask. In this case, the N-type impurities are implanted to a deeper position than that of the N-type impurities implanted during formation of the extension layer 52. Activation annealing is then performed using the RTA method or the like. The drain layer 50 including the deep layer 51 and the extension layer 52 is formed in this way.

Next, as shown in FIG. 9B, the sidewall film 57 is wet-etched with a buffered hydrogen fluoride or the like using the photoresist 59 as a mask. Accordingly, the sidewall film 57 on the drain side is removed. Meanwhile, the sidewall film 57 on the source side is left.

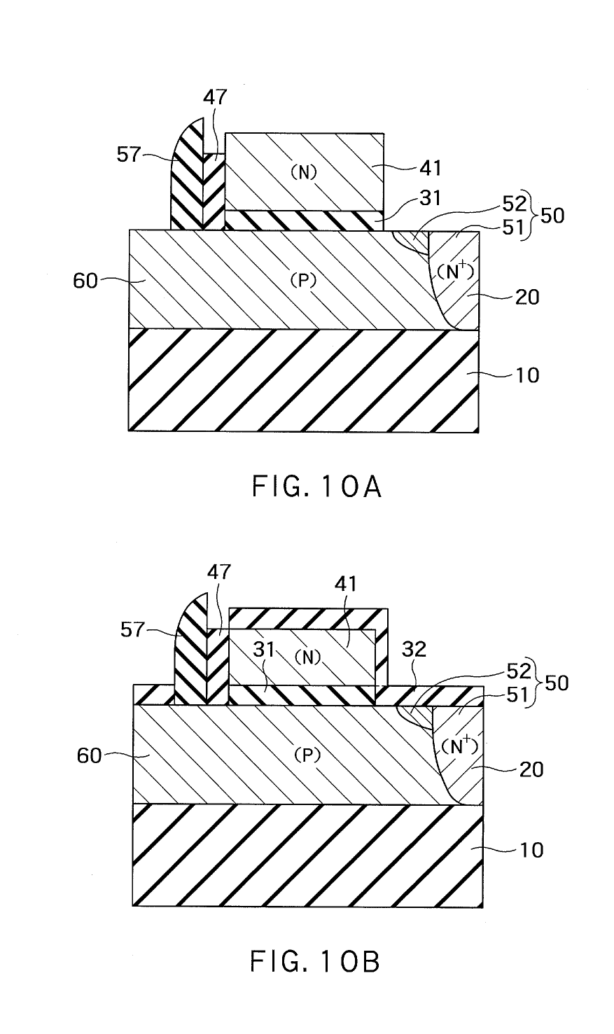

After removal of the photoresist 59, the spacer 47 and the hard mask 45 are etched using a heat phosphoric acid solution. The spacer 47 on the drain side is thereby removed as shown in FIG. 10A. Meanwhile, the spacer 47 is left between the sidewall film 57 on the source side and the first gate part 41.

Subsequently, the second gate dielectric film 32 is formed on the semiconductor layer 20. The second gate dielectric film 32 can be a thermally-oxidized film obtained by thermally oxidizing the semiconductor layer 20 or can be a TEOS film, a silicon nitride film, SiON film, a high dielectric film, or the like formed by the CVD method similarly to the first gate dielectric film 31. Unless effects of the first embodiment are impaired, materials of the first gate dielectric film 31 and the second gate dielectric film 32 can be same or different from each other.

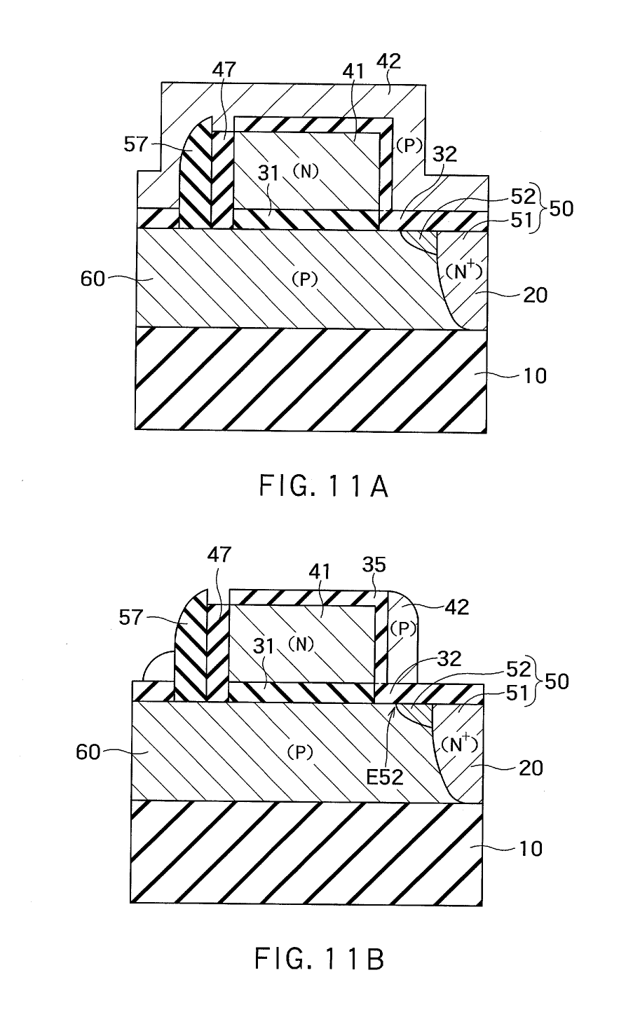

Next, as shown in FIG. 11A, a material of the second gate part 42 is deposited on the second gate dielectric film 32 using the CVD method. The material of the second gate part 42 is formed of, for example, polysilicon or polysilicon germanium doped with P-type impurities such as boron. Alternatively, the material of the second gate part 42 can be formed by implanting ions of the P-type impurities after depositing polysilicon or polysilicon germanium.

Subsequently, the material of the second gate part 42 is anisotropically etched using the RIE method. The second gate part 42 is thereby left on a side surface of the first gate part 41 on the drain side as shown in FIG. 11B. The second gate part 42 is formed on the side surface of the first gate part 41 via the material of the second gate dielectric film 32 (or with the material of the second gate dielectric film 32 interposed therebetween). At that time, the second gate part 42 is formed above the end E52 of the extension layer 52 (the drain layer 50). The material of the second gate dielectric film 32 between the second gate part 42 and the first gate part 41 is referred to as “insulating film 35” for convenience. While the material of the second gate part 42 is left also on a side surface of the sidewall film 57 on the source side, the material of the second gate part 42 on the source side is not essential.

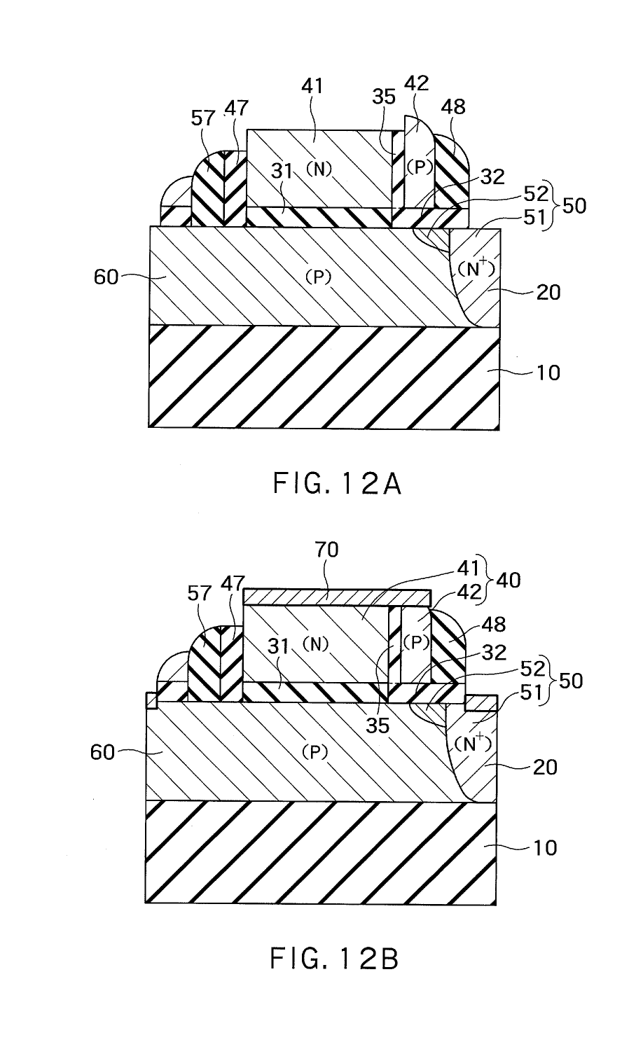

Next, a material of a spacer 48 is deposited using the CVD method. The material of the spacer 48 is an insulating film such as a silicon dioxide film or a silicon nitride film. The material of the spacer 48 is then anisotropically etched using the RIE method. Accordingly, the spacer 48 is formed to cover a side surface of the second gate part 42, and portions of the second gate dielectric film 32 on the surface of the semiconductor layer 20 in the source layer 60 and the drain layer 50 are removed as shown in FIG. 12A.

Subsequently, a metal such as Ni, Co, or Ti is deposited on the first gate part 41, the second gate part 42, the source layer 60, and the drain layer 50 using a PVD (Physical Vapor Deposition) method. By reaction between the metal layer and silicon, the silicide layer 70 is formed on the first gate part 41, the second gate part 42, the source layer 60, and the drain layer 50 as shown in FIG. 12B. The silicide layer 70 can be, for example, TiSi, Co₂Si, NiSi, NiSi₂, or NiPtSi. At that time, because a thickness of the insulating film 35 between the first gate part 41 and the second gate part 42 is as small as the second gate dielectric film 32, the silicide layer 70 electrically connects the first gate part 41 and the second gate part 42 to each other.

An interlayer dielectric film, contacts, wires, and the like are then formed, whereby the TFET 100 according to the first embodiment is completed. Although the structure of the TFET 100 shown in FIG. 1 is different from that of the TFET 100 manufactured by the manufacturing method mentioned above, these structures are equivalent in electrical characteristics.

As described above, by setting the work function of the second gate part 42 to be larger than that of the first gate part 41, the TFET 100 according to the first embodiment can generate BTBT in the channel part CH while suppressing parasitic BTBT in the PN junction part. Accordingly, the SS characteristics are improved.

Furthermore, because the threshold voltage Vth of the BTBT in the channel part CH is lower than the threshold voltage Vpara of the BTBT in the PN junction part and the threshold voltage Vth becomes dominant, variation in the threshold voltage of the TFET 100 is suppressed even when the position of the end E52 of the extension layer 52 (the drain layer 50) varies. This enables to reduce the power supply voltage and the power consumption of the TFET 100.

### Second Embodiment

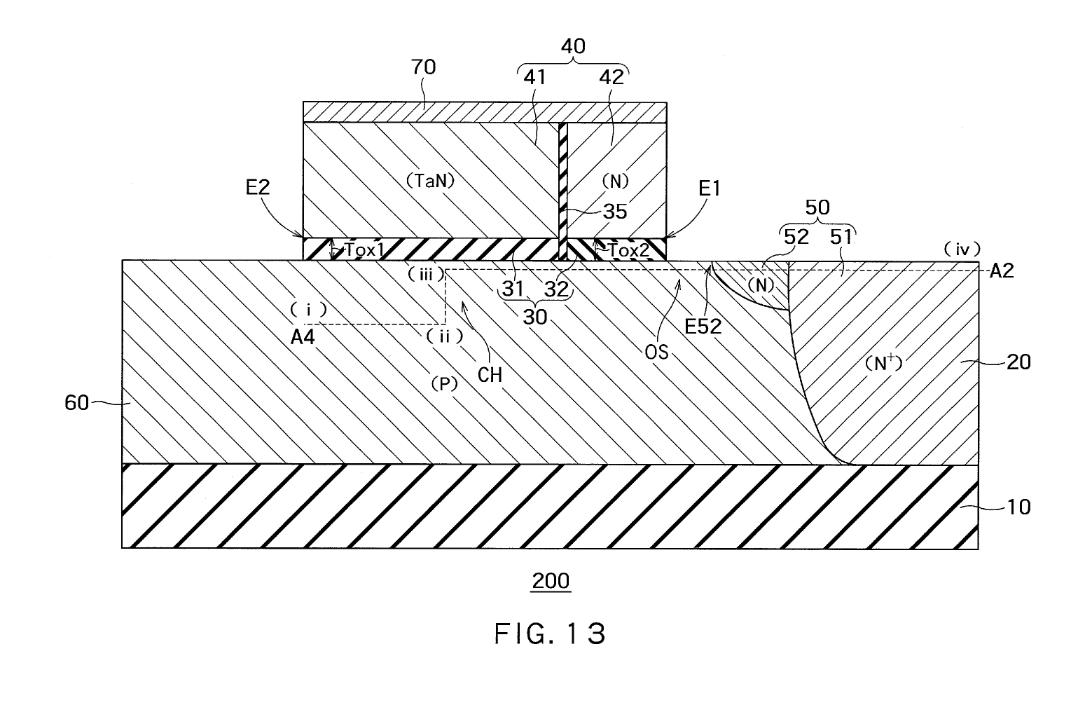

FIG. 13 is a schematic cross-sectional view showing an example of a configuration of an N-TFET 200 according to a second embodiment. In the second embodiment, the surface of the drain layer 50 does not face the bottom surface of the gate electrode 40 and the end E52 of the extension layer 52 (the drain layer 50) is not provided below the gate electrode 40. That is, the drain layer 50 is offset from the gate electrode 40, and there is the channel part CH (the source layer 60) in the semiconductor layer 20 from the end E1 of the gate electrode 40 to the end E52 of the extension layer 52. Therefore, the whole bottom surface of the gate electrode 40 faces the channel part CH (the source layer 60). In the second embodiment, the second gate part 42 has a smaller work function than that of the first gate part 41. For example, the first gate part 41 is formed of a metallic material having a relatively-high work function, such as TaN. Meanwhile, the second gate part 42 is formed of a semiconductor material having a relatively-low work function, such as N-type polysilicon. Other configurations of the second embodiment can be identical to corresponding configurations of the first embodiment.

In the TFET 200 according to the second embodiment, the drain layer 50 is offset from the gate electrode 40. Therefore, the electric field of a gate voltage is unlikely to be applied to the end E52 of the extension layer 52 and the BTBT in the PN junction part is unlikely to occur.

Meanwhile, the electric field of a gate voltage is also unlikely to be applied to a region (hereinafter, “offset region”) OS of the channel part CH between the end E1 of the gate electrode 40 and the end E52 of the extension layer 52. Therefore, if the work function of the second gate part 42 is as high as that of the first gate part 41, a depletion layer is unlikely to be formed in the offset region OS and an on-current is unlikely to flow when the gate voltage is increased.

In contrast thereto, in the second embodiment, a semiconductor material (N-type polysilicon, for example) having a relatively-low work function is used for the second gate part 42. Accordingly, energy bands in the channel part CH below the second gate part 42 and in the offset region OS near the channel part CH are previously shifted toward the valence band. This causes a depletion layer to be likely to extend in the offset region OS and the on-current to be likely to flow.

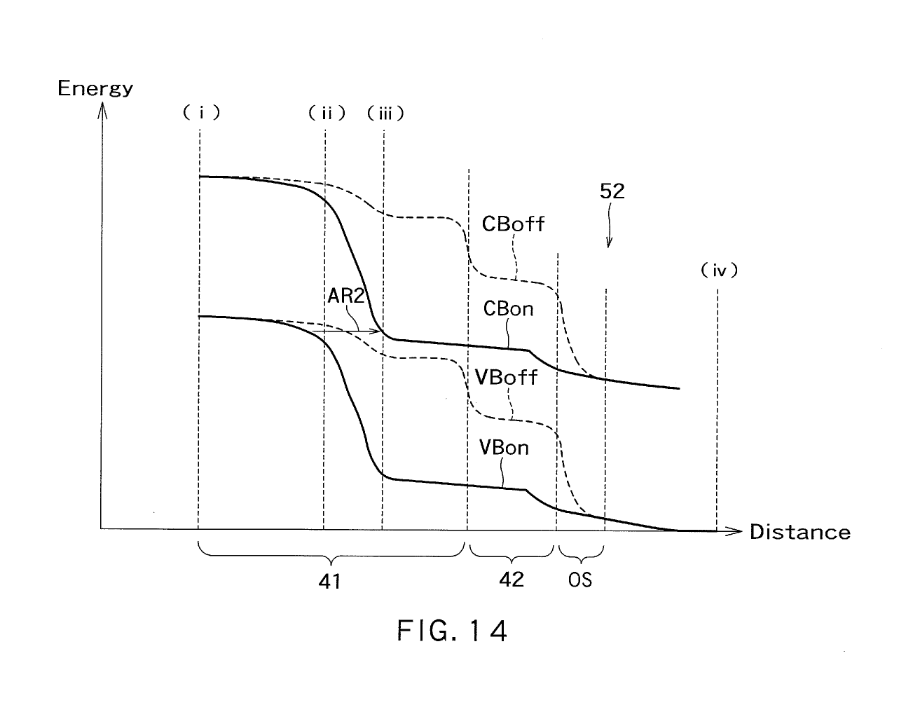

FIG. 14 illustrates energy band diagrams showing an example of an operation of the TFET 200 according to the second embodiment. FIG. 14 illustrates energy band diagrams at a position along a line A4-A2 in FIG. 13. The line A4-A2 is a line from a point (i) to a point (iv) through points (ii) and (iii) in FIG. 13.

CBoff and VBoff shown by dashed lines in FIG. 14 are energy band diagrams in a case where the TFET 200 is in an off-state, respectively. CBon and VBon shown by solid lines in FIG. 14 are energy band diagrams in a case where the TFET 200 is in an on-state, respectively.

Because the work function of the second gate part 42 is smaller than that of the first gate part 41, the energy bands CBoff and VBoff in the source layer 60 below the second gate part 42 are previously shifted toward the valence band as compared to those in the surface region of the source layer 60 below the first gate part 41 when the TFET 200 is in an off-state. That is, the energy bands CBoff and VBoff of the source layer 60 below the second gate part 42 are close to energy bands in the offset region OS.

When a positive voltage is applied to the gate electrode 40 with respect to the source voltage, the channel part CH starts depleting. Accordingly, the energy bands in the channel part CH below the first gate part 41 are bent toward the valence band as shown by CBon and VBon in FIG. 14. Along therewith, the energy bands in the channel part CH below the second gate part 42 are also bent toward the valence band.

At this time, the energy bands in the offset region OS adjacent to the second gate part 42 are also sufficiently bent toward the valence band because the energy bands CBoff and VBoff in the source layer 60 below the second gate part 42 are previously shifted toward the valence band. Therefore, a depletion layer is easily formed in the offset region OS. This facilitates formation of a channel in the source layer 60 below the second gate part 42 and in the offset region OS. As shown by an arrow AR2 in FIG. 14, when the BTBT in the channel part CH occurs, a current can easily flow between the source and the drain via a depletion layer region in the offset region OS.

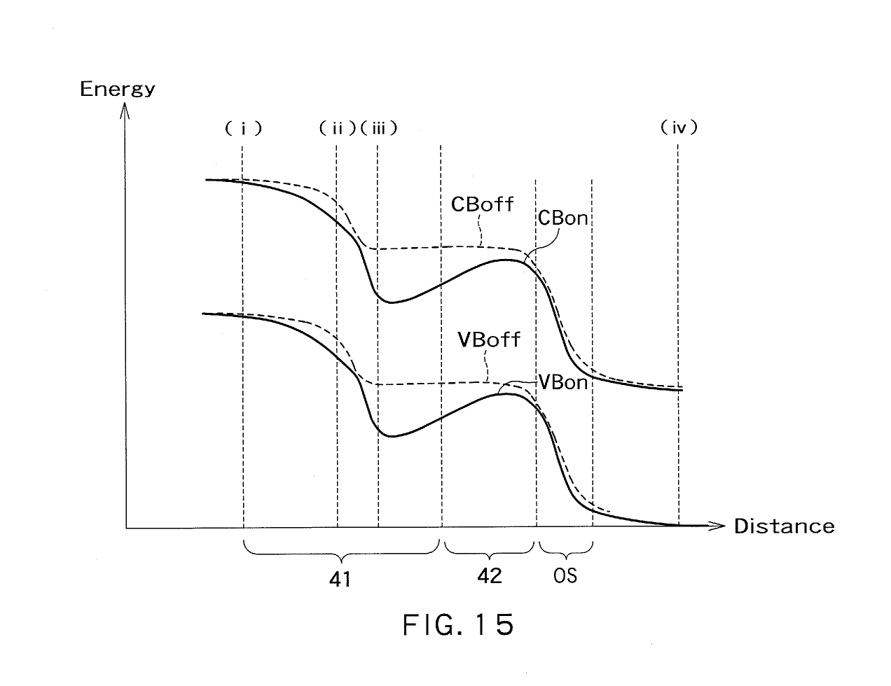

Meanwhile, FIG. 15 illustrates energy band diagrams of a TFET in which the first and second gate parts 41 and 42 have the same work function. In this case, the energy bands CBoff and VBoff are not shifted toward the valence band in the source layer 60 below the second gate part 42. Therefore, even when a gate voltage is applied, the energy bands CBon and VBon are kept high in the offset region OS as shown in FIG. 15. Accordingly, in the offset region OS, a depletion layer is unlikely to be formed and a channel is unlikely to be formed.

In contrast thereto, in the TFET 200 according to the second embodiment, because the work function of the second gate part 42 is smaller than that of the first gate part 41, the energy bands CBoff and VBoff in the surface area of the source layer 60 below the second gate part 42 are previously bent toward the valence band. Accordingly, when the gate voltage is increased, the energy bands can be sufficiently shifted toward the valence band in the source layer 60 (the channel part CH) below the second gate part 42 and in the offset region OS as shown in FIG. 14. That is, the BTBT in the channel part CH becomes likely to occur below the second gate part 42 and a depletion layer becomes likely to be formed in the offset region OS. As a result, the TFET 200 can become an on-state and a sufficient current is enabled to flow between the source and the drain.

Furthermore, in the second embodiment, the drain layer 50 is offset from the gate electrode 40 and the end E52 of the extension layer 52 is not provided below the gate electrode 40. Accordingly, the BTBT in the PN junction part is unlikely to occur and the TFET 200 can be reliably brought to an on-state by the BTBT in the channel part CH. Accordingly, the second embodiment can also achieve effects identical to those of the first embodiment.

The gate length of the second gate part 42 can be smaller or larger than that of the first gate part 41. When the gate length of the second gate part 42 is smaller than that of the first gate part 41, it is considered that almost all of the BTBT in the channel part CH occurs below the first gate part 41. When the gate length of the second gate part 42 is larger than that of the first gate part 41, it is considered that the BTBT in the channel part CH occurs below both the first gate part 41 and the second gate part 42. In either case, no problems occur because the BTBT in the PN junction part is suppressed and the BTBT in the channel part CH occurs in the channel part CH below the first gate part 41 and/or the second gate part 42.

A manufacturing method of the TFET 200 according to the second embodiment is explained next.

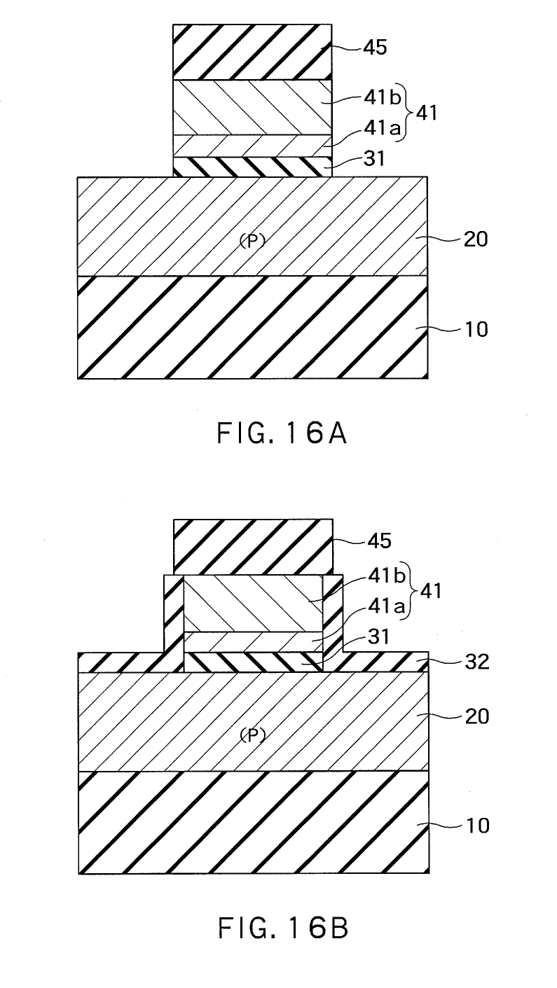

FIGS. 16A to 21 are cross-sectional views showing an example of the manufacturing method of the TFET 200 according to the second embodiment.

First, processes explained with reference to FIGS. 6A and 6B are performed to form the first gate dielectric film 31 on the semiconductor layer 20 and to form the source layer 60 and the channel part CH in the semiconductor layer 20.

Next, a material of the first gate part 41 is deposited on the first gate dielectric film 31. The first gate part 41 can have, for example, a MIPS (Metal Inserted Poly-Si Stack) structure. In this case, a material of a lower layer 41a of the first gate part 41 is formed of a metallic material such as TaN, TiN, or Ti. A material of an upper layer 41b of the first gate part 41 can be a semiconductor material such as polysilicon or a polysilicon germanium. In this case, a work function of the first gate part 41 is determined by the material of the lower layer 41a.

Subsequently, a material of the hard mask 45 is deposited on the material of the first gate part 41. The material of the hard mask 45 is formed of an insulating film such as a silicon nitride film. Next, the material of the hard mask 45 is processed into a layout pattern of the first gate part 41 using the lithography technique and the RIE method. The first gate part 41 and the first gate dielectric film 31 are processed by the RIE method using the hard mask 45 as a mask. A structure shown in FIG. 16A is thereby obtained.

Subsequently, the second gate dielectric film 32 is formed on the semiconductor layer 20. The second gate dielectric film 32 can be a thermally-oxidized film obtained by thermally oxidizing the semiconductor layer 20 or can be a TEOS film, a silicon nitride film, SiON film, a high dielectric film, or the like formed by the CVD method similarly to the first gate dielectric film 31. Unless effects of the second embodiment are impaired, materials of the first gate dielectric film 31 and the second gate dielectric film 32 can be same or different.

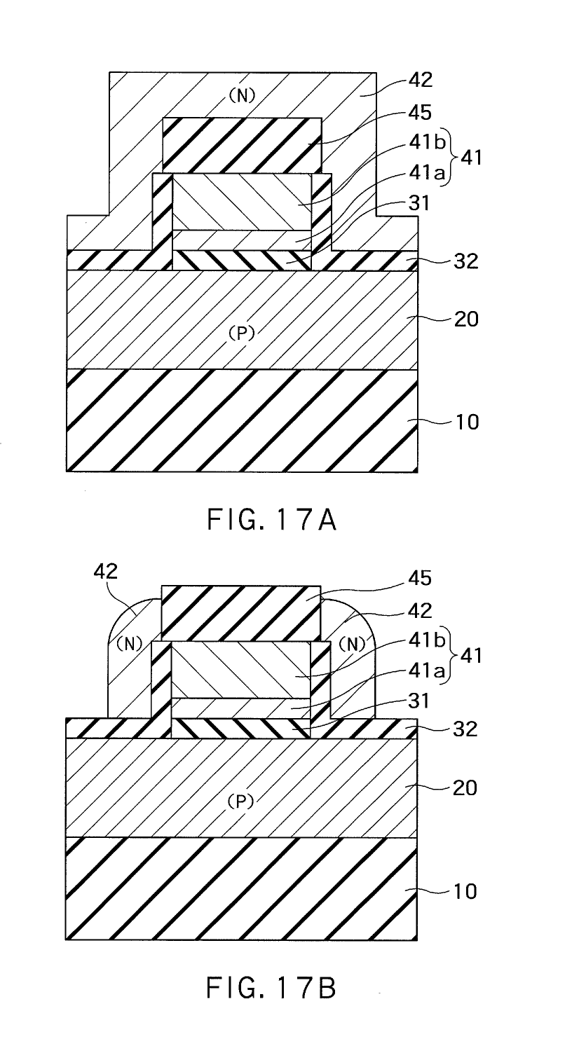

Next, a material of the second gate part 42 is deposited on the second gate dielectric film 32 using the CVD method as shown in FIG. 17A. The material of the second gate part 42 is formed of, for example, polysilicon or polysilicon germanium doped with N-type impurities. Alternatively, the material of the second gate part 42 can be formed by implanting ions of the N-type impurities after depositing polysilicon or polysilicon germanium.

Subsequently, the material of the second gate part 42 is anisotropically etched using the RIE method. The second gate part 42 is thereby left on both side surfaces of the first gate part 41 as shown in FIG. 17B. The second gate part 42 is formed on the side surfaces of the first gate part 41 via the material of the second gate dielectric film 32 (or with the material of the second gate dielectric film 32 interposed therebetween).

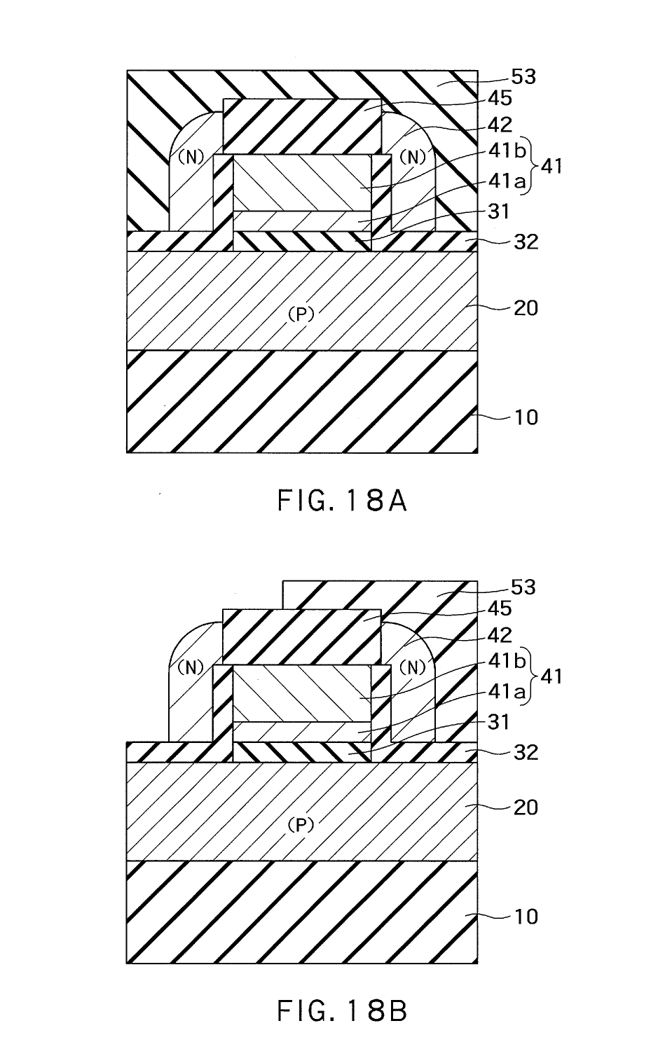

Next, a material of a hard mask 53 is deposited using the CVD method as shown in FIG. 18A. The material of the hard mask 53 is an insulating film such as a silicon dioxide film (a TEOS film) or a silicon nitride film. Alternatively, the material of the hard mask 53 can be a stacked multilayer insulating film.

Subsequently, by using the lithography technique and the etching technique, the material of the hard mask 53 on the source side is removed while the material of the hard mask 53 on the drain side is left as shown in FIG. 18B.

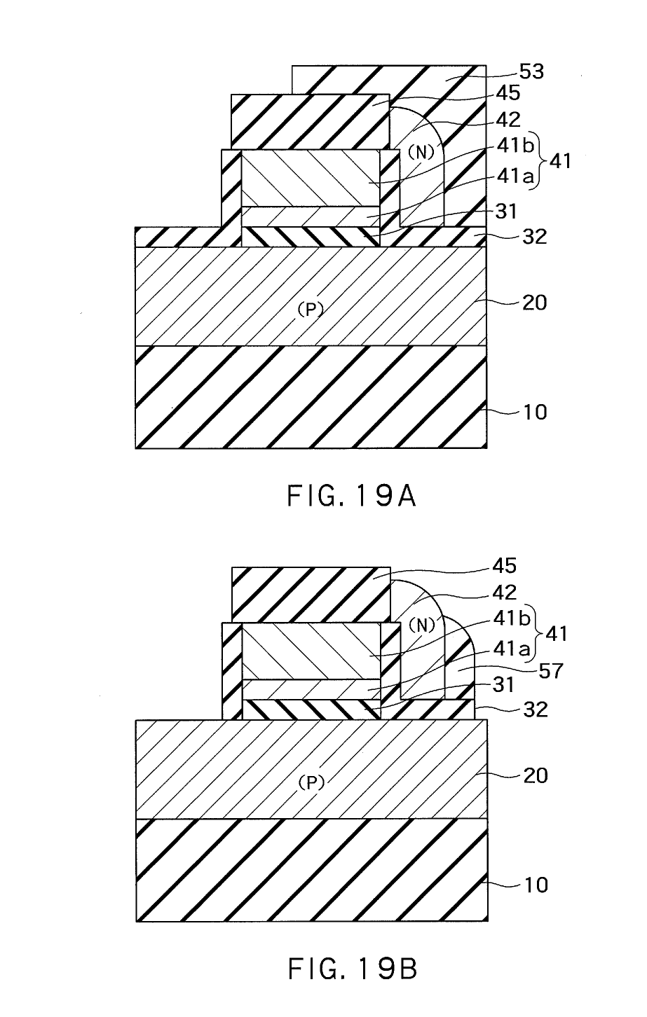

Next, for example, when the second gate part 42 is polysilicon germanium, the material of the second gate part 42 is wet-etched with a mixed solution (SC1) of NH₃ and H₂O₂, or the like, using the hard masks 53 and 45 as a mask. The material of the second gate part 42 on the source side is thereby removed while the material of the second gate part 42 on the drain side is left as shown in FIG. 19A. The second gate part 42 is thereby formed on the drain side of the first gate part 41.

Subsequently, the hard mask 53 is anisotropically etched using the RIE method. As shown in FIG. 19B, a spacer is thereby left on a side surface of the second gate part 42 on the drain side. The hard mask 53 left as the spacer is hereinafter referred to as “spacer 57”. The spacer 57 is formed to cover the side surface of the second gate part 42 on the drain side.

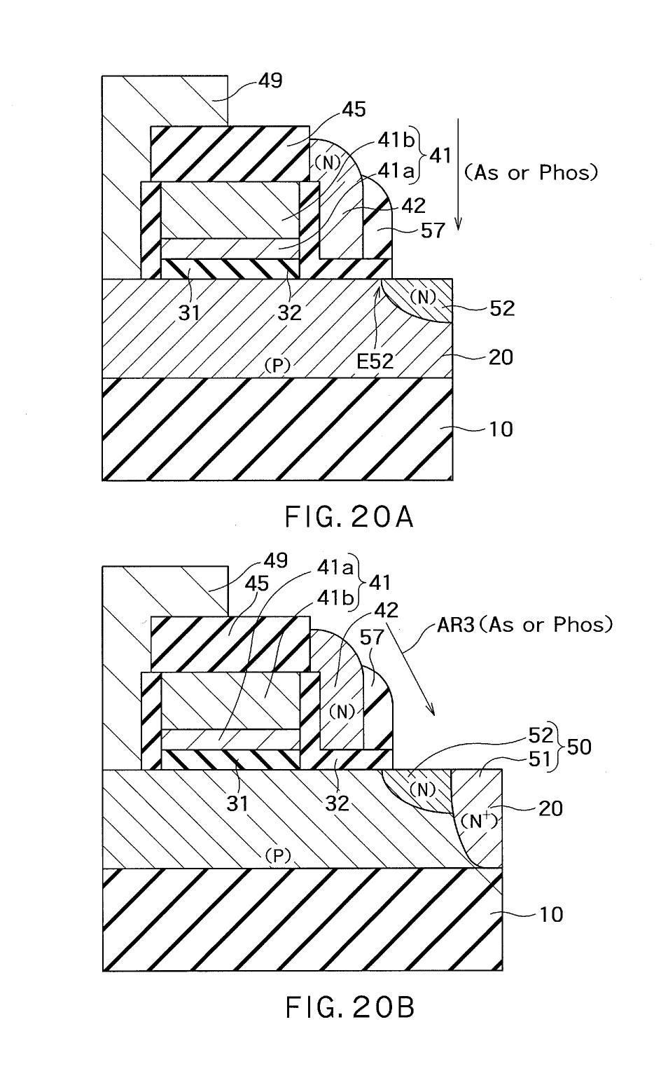

Next, the source layer 60 is covered with the photoresist 49 using the lithography technique as shown in FIG. 20A. Ions of N-type impurities are implanted to the semiconductor layer 20 on the drain side using the photoresist 49, the spacer 57, and the like as a mask. At that time, the semiconductor layer 20 on the drain side is changed from the P-type to the N-type due to implantation of the N-type impurities. The N-type impurities are locally implanted to a shallow position of the semiconductor layer 20. The impurities are implanted from a direction substantially orthogonal to the surface of the semiconductor layer 20. Accordingly, the extension layer 52 does not extend to a portion below the second gate part 42 and is formed to be offset from the second gate part 42.

Subsequently, ions of N-type impurities are implanted to the semiconductor layer 20 on the drain side using the photoresist 49, the spacer 57, and the like as a mask as shown in FIG. 20B. At that time, the impurities are implanted from a direction (a direction AR3) inclined from the direction orthogonal to the surface of the semiconductor layer 20 toward the second gate part 42. The impurities are implanted to a deeper position than that of the impurities implanted during formation of the extension layer 52. Activation annealing is then performed using the RTA method or the like. The drain layer 50 including the deep layer 51 and the extension layer 52 is formed in this way. At that time, the N-type impurities are implanted also to the second gate part 42. Therefore, the second gate part 42 becomes an N-type semiconductor layer such as N-type polysilicon due to the activation annealing.

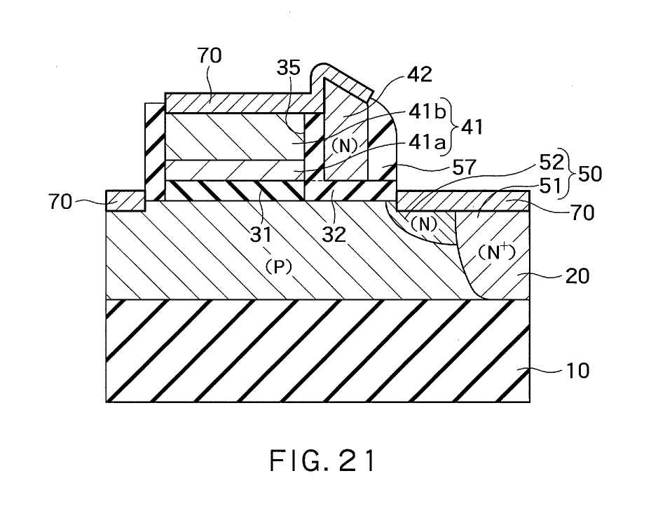

Next, after removal of the photoresist 49, the hard mask 45 is removed using a heat phosphoric acid solution or the like. Subsequently, a metal is deposited on the first gate part 41, the second gate part 42, the source layer 60, and the drain layer 50 using the PVD method. By reaction between the metal layer and silicon, the silicide layer 70 is formed on the first gate part 41, the second gate part 42, the source layer 60, and the drain layer 50 as shown in FIG. 21. The silicide layer 70 can be of the same material as that of the silicide layer 70 in the first embodiment. At that time, because the thickness of the insulating film 35 between the first gate part 41 and the second gate part 42 is as thin as the second gate dielectric film 32, the silicide layer 70 electrically connects the first gate part 41 and the second gate part 42 to each other.

An interlayer dielectric film, contacts, wires, and the like are then formed, whereby the TFET 200 is completed. Although the structure of the TFET 200 shown in FIG. 13 is different from that of the TFET 200 manufactured by the manufacturing method mentioned above, these structures are equivalent in electrical characteristics.

As described above, in the second embodiment, the drain layer 50 is offset from the gate electrode 40, and the work function of the second gate part 42 is smaller than that of the first gate part 41. Accordingly, the TFET 200 causes a depletion layer to be likely to be formed in the offset region OS while suppressing the BTBT in the PN junction part. Furthermore, the BTBT of the channel part CH is likely to occur below the second gate part 42. As a result, the TFET 200 can become an on-state stably and enables a sufficient current to flow between the source and the drain.

The TFETs 100 and 200 according to the above embodiments can be formed at the same time as a MISFET (Metal Insulation Semiconductor FET) having improved analog characteristics or high-frequency characteristics and including a plurality of gate electrodes. For example, the manufacturing methods of the TFETs 100 and 200 according to the above embodiments can be easily adapted to a manufacturing method of a so-called split gate MISFET or DWF (Dual Work Function) MISFET. The TFETs 100 and 200 according to the above embodiments thus can suppress an increase in the cost by being manufactured in combination with the MISFET including plural gate electrodes.

While the N-TFETs are explained in the above embodiments, the embodiments can be easily applied also to a P-TFET by changing conductivity types of the impurities. The P-TFET becomes an on-state when a gate voltage is lower than a threshold voltage with reference to a source voltage and becomes an off-state when a gate voltage is higher than the threshold voltage. For example, in the case of a P-TFET in a CMOS inverter, a positive voltage is applied to the source and the P-TFET is brought to an on-state by setting the gate voltage to 0 volt and is brought to an off-state by setting the gate voltage to a power supply voltage (1 volt, for example). Even in such a P-TFET, the effects of the embodiments are not impaired. However, when the above embodiments are applied to the P-TFET, a magnitude relation between the work functions of the first gate part 41 and the second gate part 42 is opposite to that in the N-TFET. That is, when the structure of the TFET 100 according to the first embodiment is applied to a P-TFET, the work function of the second gate part 42 is smaller than that of the first gate part 41. When the structure of the TFET 200 according to the second embodiment is applied to a P-TFET, the work function of the second gate part 42 is larger than that of the first gate part 41.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor layer;
a gate dielectric film on a surface of the semiconductor layer;
a gate electrode on the semiconductor layer via the gate dielectric film, the gate electrode including a first gate part and a second gate part having work functions respectively different from each other and being electrically connected to each other;
a drain layer of a first conductivity type in the semiconductor layer on a side of one end of the gate electrode; and
a source layer of a second conductivity type in the semiconductor layer on a side of the other end of the gate electrode and below the gate electrode, the source layer having a substantially uniform impurity concentration below the gate electrode.

2. The device of claim 1, wherein
the first gate part is located on a side of the source layer and the second gate part is located on a side of the drain layer,
the source layer is a P-type source layer and the drain layer is an N-type drain layer,
a work function of the second gate part is larger than that of the first gate part, and
at least a part of a surface of the drain layer faces a bottom surface of the gate electrode.

3. The device of claim 1, wherein
the first gate part is located on a side of the source layer and the second gate part is located on a side of the drain layer,
the source layer is an N-type source layer and the drain layer is a P-type drain layer,
a work function of the second gate part is smaller than that of the first gate part, and
at least a part of a surface of the drain layer faces a bottom surface of the gate electrode.

4. The device of claim 1, wherein
the first gate part is located on a side of the source layer and the second gate part is located on a side of the drain layer,
the source layer is a P-type source layer and the drain layer is an N-type drain layer,
a work function of the second gate part is smaller than that of the first gate part, and
a surface of the drain layer does not face a bottom surface of the gate electrode.

5. The device of claim 1, wherein
the first gate part is located on a side of the source layer and the second gate part is located on a side of the drain layer,
the source layer is an N-type source layer and the drain layer is a P-type drain layer,
a work function of the second gate part is larger than that of the first gate part, and
a surface of the drain layer does not face a bottom surface of the gate electrode.

6. The device of claim 1, wherein a film thickness of the gate dielectric film under the first gate part is different from that of the gate dielectric film under the second gate part.

7. The device of claim 1, wherein
the first gate part is located on a side of the source layer and the second gate part is located on a side of the drain layer, and
a gate length of the first gate part is larger than that of the second gate part.

8. The device of claim 2, wherein
the first gate part is of the first conductivity type, and
the second gate part is of the second conductivity type.

9. The device of claim 3, wherein
the first gate part is of the first conductivity type, and
the second gate part is of the second conductivity type.

10. The device of claim 4, wherein
the first gate part is formed of a metallic material, and
the second gate part is formed of a semiconductor material.

11. The device of claim 2, wherein a film thickness of the gate dielectric film under the second gate part is larger than that of the gate dielectric film under the first gate part.

12. The device of claim 3, wherein a film thickness of the gate dielectric film under the second gate part is larger than that of the gate dielectric film under the first gate part.

13. The device of claim 1, further comprising a conducting layer on the gate electrode, the conducting layer electrically connecting between the first gate part and the second gate part.

14. A semiconductor device comprising:
a semiconductor layer;
a gate dielectric film on a surface of the semiconductor layer;
a gate electrode on the semiconductor layer via the gate dielectric film, the gate electrode including a first gate part and a second gate part having work functions respectively different from each other and being electrically connected to each other;
a drain layer of a first conductivity type in the semiconductor layer on a side of one end of the gate electrode; and
a source layer of a second conductivity type in the semiconductor layer on a side of the other end of the gate electrode and below the gate electrode, the source layer having a substantially uniform impurity concentration below the gate electrode, wherein
the first gate part is located on a side of the source layer and the second gate part is located on a side of the drain layer,
a work function of the second gate part is larger than that of the first gate part when the source layer is a P-type source layer and the drain layer is an N-type drain layer,
a work function of the second gate part is smaller than that of the first gate part when the source layer is an N-type source layer and the drain layer is a P-type drain layer, and
at least a part of a surface of the drain layer faces a bottom surface of the gate electrode.

15. The device of claim 14, wherein a film thickness of the gate dielectric film under the first gate part is different from that of the gate dielectric film under the second gate part.

16. The device of claim 14, wherein
a gate length of the first gate part is larger than that of the second gate part.

17. The device of claim 14, further comprising a conducting layer on the gate electrode, the conducting layer electrically connecting between the first gate part and the second gate part.

18. A semiconductor device comprising:
a semiconductor layer;
a gate dielectric film on a surface of the semiconductor layer;
a gate electrode on the semiconductor layer via the gate dielectric film, the gate electrode including a first gate part and a second gate part having work functions respectively different from each other and being electrically connected to each other;
a drain layer of a first conductivity type in the semiconductor layer on a side of one end of the gate electrode; and
a source layer of a second conductivity type in the semiconductor layer on a side of the other end of the gate electrode and below the gate electrode, the source layer having a substantially uniform impurity concentration below the gate electrode, wherein
the first gate part is located on a side of the source layer and the second gate part is located on a side of the drain layer,
a work function of the second gate part is smaller than that of the first gate part when the source layer is a P-type source layer and the drain layer is an N-type drain layer,
a work function of the second gate part is larger than that of the first gate part when the source layer is an N-type source layer and the drain layer is a P-type drain layer, and
a surface of the drain layer does not face a bottom surface of the gate electrode.

19. The device of claim 18, wherein a film thickness of the gate dielectric film under the first gate part is different from that of the gate dielectric film under the second gate part.

20. The device of claim 18, further comprising a conducting layer on the gate electrode, the conducting layer electrically connecting between the first gate part and the second gate part.
